(19) United States
(12) Patent Application Publication
(10) Pub. No.: US 2005/0005436 A1
(43) Pub. Date: Jan. 13, 2005

(54) Method for preparing thin integrated circuits with multiple circuit layers

(76) Inventor: Jung-Chien Chang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/615,139

(22) Filed: Jul. 9, 2003

(51) Int. Cl. H05K 3/20; B05D 5/12

(52) U.S. Cl. 29/841; 29/846; 29/831

(57) ABSTRACT

A method for preparing thin integrated circuits having multiple circuit layers has the following acts of: forming a first circuit layer on a substrate; depositing at least one resin and copper layer on the first circuit layer; forming a second circuit layer on the at least one resin and copper layer; electrically connecting the first and second circuit layers; attaching electronic components to the first or second circuit layers; applying an encapsulant layer to protect the electronic components; and removing the substrate to expose the first circuit layer. By removing the substrate, the integrated circuit is much thinner.

### BACKGROUND OF THE INVENTION

1. Field of the Invention

The present invention relates to a method for preparing thin integrated circuits, and more particularly to a method for preparing thin integrated circuits that constructs multiple circuit layers without using printed circuit board.

2. Description of Related Art

To meet the demands of integrating multiple functions in an electronic device, design of integrated circuits has become complex in direct proportion to the increased number of functions. However, size of integrated circuits is severely limited by the size of the device in which the integrated circuits must be installed. Consequently, creating a complex integrated circuit having multiple functions and meeting severe space limitations is a key-point of research and development.

Because multi-function integrated circuits are essential to the production of small modern electronic devices and the requisite functions cannot be implemented in a small enough package on a single-layer circuit, multi-layer integrated circuit have been developed. However, the multiple-layer integrated circuit is composed of multiple printed circuit boards bonded together and an encapsulant layer formed on an outer surface to protect discrete electronic components. Therefore, a multi-layer integrated circuit is thick. When more functions are integrated into the multi-layer integrated circuit, the multi-layer integrated circuit is thicker, and the thickness of the printed circuit board becomes a design limit.

The present invention has arisen to mitigate or obviate the disadvantages of the conventional multi-layer integrated circuit.

### SUMMARY OF THE INVENTION

A first objective of the present invention is to provide a method for preparing thin integrated circuits having multiple circuit layers to reduce production cost and diminish sizes of the integrated circuits.

A second objective of the present invention is to provide a method for preparing thin integrated circuits having multiple circuit layers that nearly have a thickness of an encapsulant layer.

Further benefits and advantages of the present invention will become apparent after a careful reading of the detailed description in accordance with the drawings.

### BRIEF DESCRIPTION OF THE DRAWINGS

FIG. 1 is a side plan view of a substrate for a thin integrated circuit in accordance with the present invention;

FIG. 2 is a side plan view of a first circuit layer formed on the substrate in FIG. 1;

FIG. 3 is a side plan view of a resin-copper coating laminated on the first circuit layer in FIG. 2;

FIG. 4 is a side plan view of holing microvias in the resin-copper coating to reach the first circuit layer;

FIG. 5 is an operational side plane view of forming the a conductive layer on the resin-copper coating into the microvias to construct a conductive hole;

FIG. 6 is an operational side plane view of forming photo-resisting areas and a second circuit layer on the conductive layer;

FIG. 7 is an operational side plane view of removing the photo-resisting areas and parts of conductive layer and resin-copper coating;

FIG. 8 is an operational side plane view of attaching multiple electronic components on the second circuit layer;

FIG. 9 is an operational side plane view of applying a encapsulant layer covering the second circuit layer and the multiple electronic components, wherein the substrate is removed;

FIG. 10 is an operational side plane view of forming an isolating layer between two parts of the first circuit layer and forming a tin-paste layer between two isolating layers at dimples;

FIG. 11 is a side plane view of another substrate in the thin integrated circuit in accordance with present invention, wherein the substrate has no dimples;

FIG. 12 is an operational side plane view of forming the first circuit layer, the resin-copper coating, the conductive layer, the conductive hole, the second circuit layer and multiple electronic components on the substrate in FIG. 11;

FIG. 13 is an operational side plane view of another procedure to form photo-resisting areas on the conductive layer; and

FIG. 14 is an operational side plane view of the procedure of FIG. 13 to remove a copper layer before forming the second circuit layer.

### DETAILED DESCRIPTION OF THE PREFERRED EMBODIMENT

A method for preparing thin integrated circuits having multiple circuit layers in accordance with the present invention accommodates any number of circuit layers to meet the functional requirements of a particular integrated circuit. For purposes of illustration only, a specific embodiment of the method for preparing thin integrated circuit describes a method of preparing a thin integrated circuit with two circuit layers. Acts in the method can be iterated to form any number of layers required or desired.

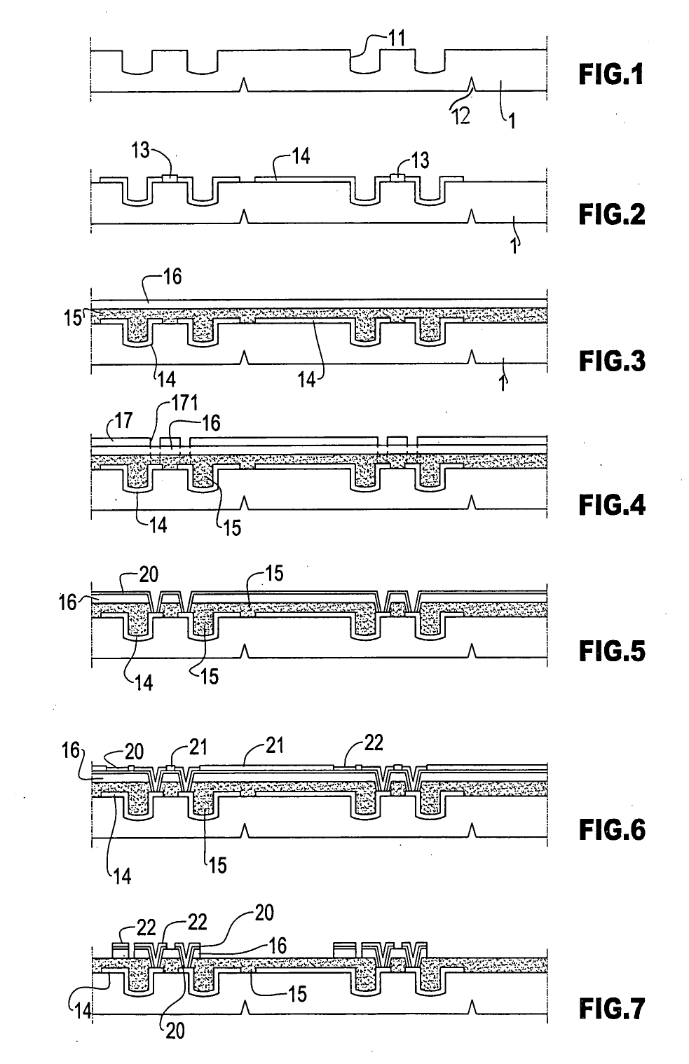

The method for preparing thin integrated circuits having multiple circuit layers comprises the following acts:
forming a first circuit layer with multiple sections on a substrate;
depositing a resin-copper coating on the first circuit layer;
forming a second circuit layer with multiple sections on the resin-copper coating;
electrically connecting the first and second circuit layers;
connecting electronic components to the second circuit layer;
applying an encapsulant layer to protect the electronic components; and
removing the substrate to expose the first circuit layer.
With reference to FIG. 1, a substrate (1) made of copper is obtained and has a top face (not numbered), a bottom face (not numbered), multiple dimples (11) and multiple cutting grooves (12). The dimples (11) are defined in the top face, and the cutting grooves (12) are defined in the bottom face. Two intersecting pairs of adjacent cutting grooves (12) define a unit (not numbered) of the integrated circuit.

With reference to FIG. 2, photo-resist (13) is applied to a first area on the top face of the substrate (1) between adjacent dimples (11) within the integrated circuit unit. Then, a first circuit layer (14) is electroplated on areas of the top face of the substrate (1) without the photo-resist (13). The first circuit layer (14) is anticorrosive, and gold or aluminum wires can be bonded to the first circuit layer (14). The first circuit layer (14) is metal suitable for lead-tin solder and is composed optionally of copper/nickel/copper/purity nickel/purity gold, purity nickel/purity gold, purity nickel/gold/palladium, etc. After electroplating the first circuit layer (14) on the substrate (1), the photo-resist (13) is removed.

With reference to FIG. 3, an organic adhesive layer (not numbered) is formed on the first circuit layer (14). In this embodiment, the organic adhesive layer is a resin-copper coating (not numbered) composed of a resin layer (15) and a copper layer (16) and is attached to the first circuit layer (14) by high-temperature compression.

With reference to FIGS. 4 and 5, a laser resistant layer (17) with multiple windows (171) is attached to the resin-copper coating so microvias can be formed in the resin-copper coating. Then, a laser beam burns out the resin-copper coating in the windows (171) to the first circuit layer (14) by controlling the laser beam to form the microvias. Next, the laser resistant layer (17) is removed, and a conductive layer (20) is applied to the resin-copper coating and extends into the microvias to electrically connect the copper layer (16) to the first circuit layer (14) so the microvias become conductive holes.

With reference to FIGS. 6 and 7, second photo-resist (21) is applied by photo-mask to multiple second areas on the conductive layer (20) according to a circuit design. In this preferred embodiment, a positive-film process is carried out to apply a second circuit layer (22) to areas of the conductive layer (20) without the photo-resist. The second circuit layer (22) also extends into the conductive holes. Then, the second photo-resist (21) at the second areas, the underlying conductive layer (20) and copper layer (16) are removed by etching to form gaps (not numbered). Additionally, if a third circuit layer (not shown) or other sequential circuit layer is designed to constructed on the integrated circuit, operational steps are repeated from forming the resin-copper layer in FIG. 3 on the second circuit layer (22) to forming an outer circuit layer in FIG. 7. Whereby, multiple circuit layers are constructed on the integrated circuit and electrically connect with each other, and the electronic components are applied to the topmost circuit layer. The operational steps are repeated to increase a consequential circuit layer for each time to achieve multiple circuit layers on the integrated circuit.

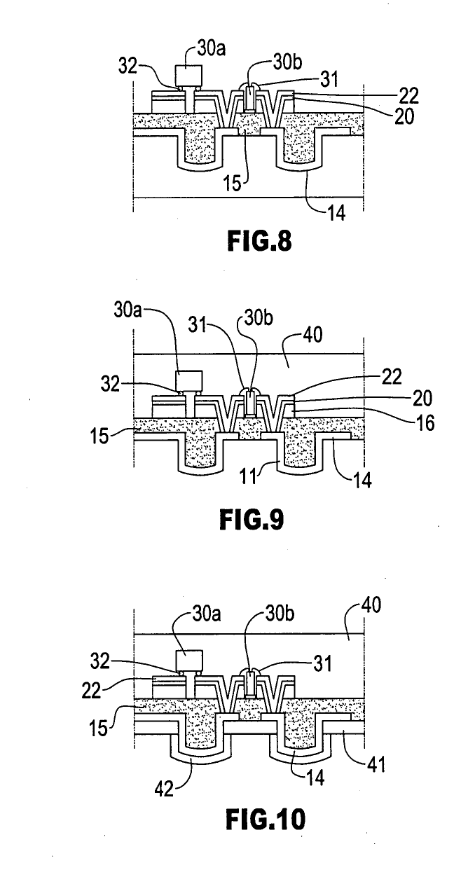

With reference to FIG. 8, the substrate (1) is divided into units along the cutting grooves (12). Multiple electronic components (30a, 30b) are attached to the second circuit layer (22) at different places. A first electronic component (30a) is attached to the second circuit layer (22) by soldering tin balls (32) and bridges on the gap to connect different sections of the circuit on the second circuit layer (22). A second electronic component (30b) is embedded inside the gap and bonded with silver-filled epoxy (silver paste) to the resin layer (15), and multiple metal wires (31) are bonded around the second electronic component (30b) to electrically connect the second electronic component (30b) to the different sections of circuit on the second circuit layer (22).

With reference to FIG. 9, an encapsulant layer (40) is applied to the second circuit layer (22) after attaching the multiple electronic components (30a, 30b) and covers the multiple electronic components (30a, 30b) to protect the second circuit layer (22) and the multiple electronic components (30a, 30b). Then, the substrate (1) is etched and removed from the bottom face to expose the first circuit layer (14) and sections of the resin layer (15). With the substrate (1) removed, the first circuit layer (14) at the dimples (11) in the substrate (1) become protrusions (not numbered) that can connect to other circuit boards.

With further reference to FIG. 10, an isolating layer (41) is optionally formed over gaps in the first circuit layer (14), and a tin-paste layer (42) is applied to the first circuit layer (14) between adjacent isolating layers (41) to easily solder and electrically connect to other circuit boards. Whereby, a thin integrated circuit is achieved.

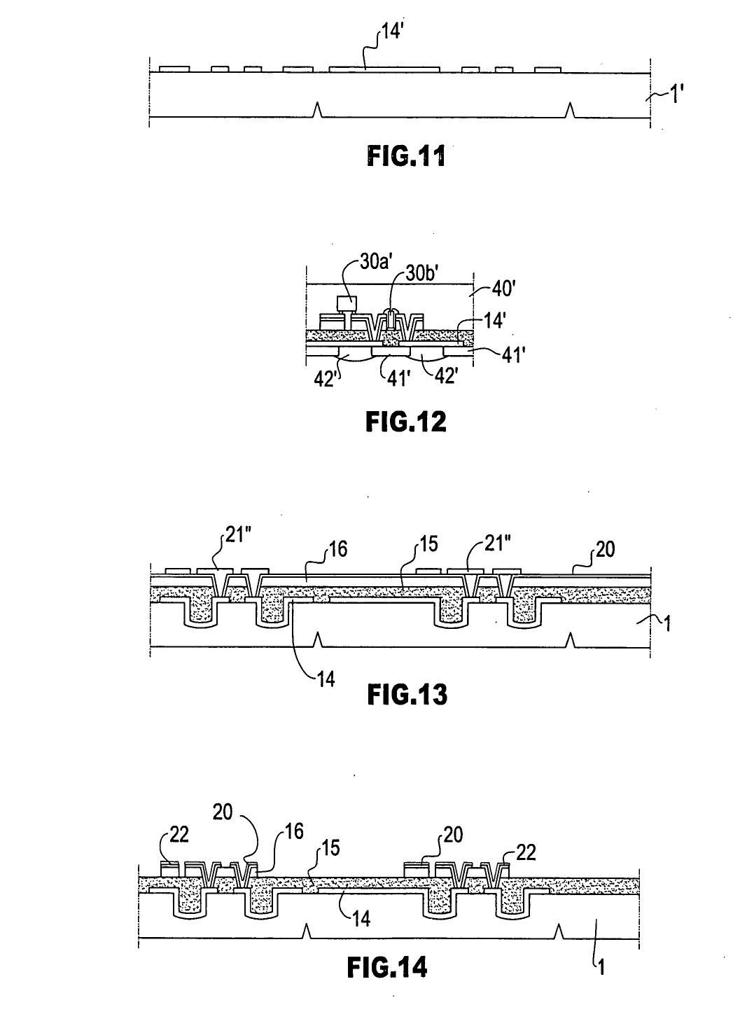

With reference to FIGS. 11 and 12, another embodiment of the integrated circuit that has a flat substrate (1′) without dimples. The first circuit layer (14′) and other layers are formed on the substrate (1′) with the same method previously described. Moreover, the flat substrate (1′) is also removed by etching to expose the first circuit layer (14′). Finally, the isolating layers (41′) and the tin-paste layers (42′) are formed on the first circuit layer (14′) to achieve the integrated circuit. Since the first circuit layer (14′) does not have any protrusions, the thickness of the integrated circuit is reduced to diminish the size of the integrated circuit.

Additionally, with reference to FIGS. 13 and 14, a negative-film process is performed instead of the previously described positive-film process to etch away the conductive layer (20) and the copper layer (16). Second photo-resist (21″) is applied to the conductive layer (20) in second areas based on the circuit design where the conductive layer (20) and the copper layer (16) are to be retained. After etching away the desired conductive layer (20) and copper layer (16), the second photo-resist (21″) is removed from the second areas, and a second circuit layer (22) is electroplated on the conductive layer (20). Since the resin layer (15) is not conductive material, the second circuit layer (22) only electroplates on the conductive layer (20) and exposed surfaces of the copper layer (16). Other procedures of attaching the multiple electronic components (not shown) and packaging with the encapsulant layer are the same as those previously described.

Removing the substrate causes the integrated circuit to be much thinner than the conventional integrated circuit. Therefore, the thin integrated circuit having multiple circuit layers is much smaller but performs all required functions.

Although the invention has been explained in relation to its preferred embodiment, many other possible modifications and variations can be made without departing from the spirit and scope of the invention as hereinafter claimed.

1. A method for preparing thin integrated circuits having multiple circuit layers comprising the following acts:
forming a first circuit layer with multiple sections on a substrate;
depositing a resin-copper coating on the first circuit layer;
forming a second circuit layer with multiple sections on the resin-copper coating to serve as a topmost circuit layer on the substrate;
electrically connecting the first and second circuit layers;
connecting electronic components to the topmost circuit layer;
applying an encapsulant layer to protect the electronic components; and
removing the substrate to expose the first circuit layer.

2. The method as claimed in claim 1, wherein multiple dimples are defined in the substrate before the first circuit layer is formed on the substrate including the dimples;
whereby the first circuit layer at the dimples become protrusions after the substrate is removed.

3. The method as claimed in claim 1, wherein the substrate has a flat top face and the first circuit layer is formed on the substrate in flat.

4. The method as claimed in claim 1, wherein the first and second circuit layers are electronically connected by forming microvias through the resin-copper coating from the first circuit layer to the second circuit layer and;
forming a conductive layer on the second circuit layer into the microvias to connect between the first and second circuit layers.

5. The method as claimed in claim 1, wherein the electronic components are connected to the second circuit layer by bonding metal wires between the electronic components and the second circuit layer.

6. The method as claimed in claim 2, wherein the electronic components are connected to the second circuit layer by bonding metal wires between the electronic components and the second circuit layer.

7. The method as claimed in claim 3, wherein the electronic components are connected to the second circuit layer by bonding metal wires between the electronic components and the second circuit layer.

8. The method as claimed in claim 4, wherein the electronic components are connected to the second circuit layer by bonding metal wires between the electronic components and the second circuit layer.

9. The method as claimed in claim 1, wherein the electronic components are connected to the second circuit layer by soldering tin balls between the electronic components and the second circuit layer.

10. The method as claimed in claim 2, wherein the electronic components are connected to the second circuit layer by soldering tin balls between the electronic components and the second circuit layer.

11. The method as claimed in claim 3, wherein the electronic components are connected to the second circuit layer by soldering tin balls between the electronic components and the second circuit layer.

12. The method as claimed in claim 4, wherein the electronic components are connected to the second circuit layer by soldering tin balls between the electronic components and the second circuit layer.

13. The method as claimed in claim 1, wherein multiple isolating layers are respectively applied to adjacent sections of the exposed first circuit layer after the substrate is removed and multiple tin-paste layers are respectively applied to the first circuit layer between adjacent isolating layers.

14. The method as claimed in claim 2, wherein multiple isolating layers are respectively applied to adjacent sections of the exposed first circuit layer after the substrate is removed and multiple tin-paste layers are respectively applied to the first circuit layer between adjacent isolating layers.

15. The method as claimed in claim 3, wherein multiple isolating layers are respectively applied to adjacent sections of the exposed first circuit layer after the substrate is removed and multiple tin-paste layers are respectively applied to the first circuit layer between adjacent isolating layers.

16. The method as claimed in claim 4, wherein multiple isolating layers are respectively applied to adjacent sections of the exposed first circuit layer after the substrate is removed and multiple tin-paste layers are respectively applied to the first circuit layer between adjacent isolating layers.

17. The method as claimed in claim 1, wherein the method further comprises the following acts before applying the electronic components to the topmost circuit layer,
depositing a resin-copper coating on the second circuit layer after the second circuit layer is constructed;
forming a third circuit layer with multiple sections on the resin-copper coating to serve as the topmost circuit layer on the substrate;
electrically connecting the second and third circuit layers; and
connecting the electronic components to the topmost circuit layer;
wherein the acts are repeated to increase a consequential circuit layer for each time to achieve multiple circuit layers on the integrated circuit.
